(19) United States
(12) Patent Application Publication
(10) Pub. No.: US 2025/0132274 A1
(43) Pub. Date: Apr. 24, 2025

(54) SEMICONDUCTOR CHIP AND SEMICONDUCTOR PACKAGE INCLUDING THE SAME

(71) Applicant: SAMSUNG ELECTRONICS CO., LTD., SUWON-SI (KR)

(72) Inventors: HANSUNG RYU, Suwon-si (KR); JONGBEOM PARK, Suwon-si (KR)

(21) Appl. No.: 18/676,989

(22) Filed: May 29, 2024

(30) Foreign Application Priority Data
Oct. 18, 2023 (KR) 10-2023-0139619

(51) Int. Cl. H01L 23/00; H01L 23/48; H01L 23/522; H01L 25/065; H10B 80/00

(52) U.S. Cl. CPC H01L 24/05; H01L 23/481; H01L 23/5226; H01L 24/08; H01L 25/0657; H10B 80/00; H01L 2224/05567; H01L 2224/08145

(57) ABSTRACT

A semiconductor chip includes a substrate; a front wiring structure on a front surface of the substrate and that includes a first insulation layer, a second insulation layer on the first insulation layer, a wiring pad, a first connection pad, and a plurality of first vias that electrically connect the wiring pad and the first connection pad; a rear wiring structure on a rear surface of the substrate and that includes a second connection pad; and a through via that penetrates the substrate and the first insulation layer and electrically connects the front wiring structure and the rear wiring structure. A dielectric constant of the first insulation layer is lower than a dielectric constant of the second insulation layer, the wiring pad is located at an interface of the first insulation layer and the second insulation layer, and the first connection pad is embedded in the second insulation layer.

### CROSS-REFERENCE TO RELATED APPLICATION

This application claims priority under 35 U.S.C. 119 from Korean Patent Application No. 10-2023-0139619, filed in the Korean Intellectual Property Office on Oct. 18, 2023, the contents of which are herein incorporated by reference in their entirety.

### TECHNICAL FIELD

Embodiments of the present disclosure are directed to a semiconductor chip and a semiconductor package including the same.

### DISCUSSION OF THE RELATED ART

As electronic devices are down-sized, various technologies are being researched to satisfy semiconductor package characteristics, such as lightness, thinness, shortness, excellent reliability, high performance, and large capacity.

One such technology is a hybrid bonding technology in which semiconductor chips that include through silicon vias (TSV) are stacked in a vertical direction and connection pads of the stacked semiconductor chips are directly bonded.

According to temperature changes due to a high temperature storage test (HTS), a temperature cycling test (TC), etc., a stress is concentrated on a wiring pad connected to the TSV of the hybrid bonded semiconductor chips, which can cause interface cracks with an insulation layer. For example, this phenomena may be increased by using the insulation layer with a low dielectric constant. These interface cracks also affect the reliability of the semiconductor chips.

Therefore, a new semiconductor chip and a semiconductor package that includes the same that can reduce the stress applied to the wiring pad due to the temperature changes are desired.

### SUMMARY

An embodiment of the present disclosure provides a semiconductor chip that reduces the stress applied to the wiring pad due to temperature changes and a semiconductor package that includes the same.

Another embodiment of the present disclosure provides a semiconductor chip with improved reliability and a semiconductor package that includes the same.

An embodiment of the present disclosure provides a semiconductor chip that includes a substrate; a front wiring structure disposed on a front surface of the substrate, where the front wiring structure includes a first insulation layer, a second insulation layer placed on the first insulation layer, a wiring pad, a first connection pad, and a plurality of first vias that electrically connect the wiring pad and the first connection pad; a rear wiring structure disposed on a rear surface of the substrate and that includes a second connection pad; and a through via that penetrates the substrate and the first insulation layer and electrically connects the front wiring structure and the rear wiring structure. A dielectric constant of the first insulation layer is lower than a dielectric constant of the second insulation layer. The wiring pad is disposed at an interface of the first insulation layer and the second insulation layer. The first connection pad is embedded in the second insulation layer. The plurality of first vias is in contact with each of the wiring pad and the first connection pad, and the through via is in contact with the wiring pad.

Another embodiment of the present disclosure provides a semiconductor chip that includes a substrate; a front wiring structure disposed on a front surface of the substrate, where the front wiring structure includes a first insulation layer, a second insulation layer disposed on the first insulation layer, and a first connection pad; a rear wiring structure disposed on a rear surface of the substrate and that includes a second connection pad; and a through via that penetrates the substrate and the first insulation layer and electrically connects the front wiring structure and the rear wiring structure. A dielectric constant of the first insulation layer is lower than a dielectric constant of the second insulation layer. A first surface of the first connection pad is covered by the first insulation layer, a second surface of the first connection pad opposite to the first surface is exposed by the second insulation layer, and the through via is in contact with the first surface of the first connection pad.

Another embodiment of the present disclosure provides a semiconductor package that includes a first semiconductor chip; and a second semiconductor chip bonded with the first semiconductor chip. The first semiconductor chip includes a first substrate; a front wiring structure disposed on the front surface of the first substrate, where the front wiring structure includes a first insulation layer, a second insulation layer disposed on the first insulation layer, a wiring pad, a first connection pad, and a plurality of first vias that electrically connect the wiring pad and the first connection pad; a rear wiring structure disposed on a rear surface of the first substrate and that includes a second connection pad; and a through via that penetrates the first substrate and the first insulation layer and electrically connects the front wiring structure and the rear wiring structure. The second semiconductor chip includes a second substrate; and a third connection pad disposed on the second substrate. A dielectric constant of the first insulation layer is lower than a dielectric constant of the second insulation layer. The wiring pad is located at an interface of the first insulation layer and the second insulation layer. The first connection pad is embedded in the second insulation layer. The plurality of first vias is in contact with each of the wiring pad and the first connection pad. The through via is in contact with the wiring pad, and the first connection pad and the third connection pad are in contact with and bonded to each other.

According to an embodiment of the present disclosure, there is provided a semiconductor chip that reduces a stress applied to the wiring pad due to temperature changes and a semiconductor package that includes the same.

According to another embodiment of the present disclosure, there are provided semiconductor chips with increased reliability and semiconductor packages that contain them.

### BRIEF DESCRIPTION OF THE DRAWINGS

FIG. 1 is a cross-sectional view of a semiconductor chip according to an embodiment of the present disclosure.

FIG. 2 is a cross-sectional view of a semiconductor chip according to another embodiment of the present disclosure.

FIG. 3 is a cross-sectional view of a semiconductor chip according to another embodiment of the present disclosure.

FIG. 4 is a cross-sectional view of a semiconductor chip according to another embodiment of the present disclosure.

FIG. 5 is a cross-sectional view of a semiconductor package that includes a semiconductor chip according to an embodiment of the present disclosure.

FIG. 6 is a cross-sectional view of another semiconductor package that includes a semiconductor chip according to an embodiment of the present disclosure.

FIG. 7 is a cross-sectional view of a package that includes a semiconductor package of FIG. 5.

### DETAILED DESCRIPTION

Embodiments of the present disclosure will be described more fully hereinafter with reference to the accompanying drawings, in which embodiments of the disclosure are shown. As those skilled in the art would realize, described embodiments may be modified in various different ways, all without departing from the spirit or scope of the present disclosure.

Throughout the specification, when it is described that a part is “connected to” another part, the part may be “directly connected” to the other element or “connected” to the other part through a third part. In a similar sense, this includes being “physically connected” as well as being “electrically connected”. However, when it is described that a part is “in contact with” another part, no intervening third part is present.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a semiconductor chip according to embodiments of the present disclosure will be described with reference to accompanying drawings.

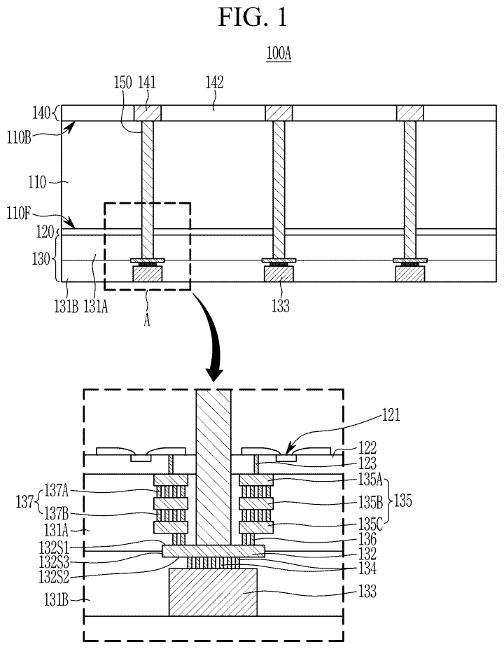

FIG. 1 is a cross-sectional view of a semiconductor chip according to an embodiment of the present disclosure.

Referring to FIG. 1, in an embodiment, a semiconductor chip 100A includes a substrate 110, a front circuit structure 120, a front wiring structure 130, a rear wiring structure 140, and a through via 150.

The substrate 110 has a front surface 110F and a rear surface 110B, which is the opposite side of the front surface 110F. As described below, the front circuit structure 120 is disposed on the front surface 110F. In the technical field to which embodiments of the present disclosure belong, the front surface 110F of the substrate 110 on which the front circuit structure 120 is formed may be referred to as an active layer, and the rear surface 110B may be referred to as an inactive surface.

The substrate 110 is a semiconductor substrate that includes at least one of silicon (Si), germanium (Ge), gallium arsenide (GaAs), or silicon carbide (Sic).

The front circuit structure 120 is disposed on the front surface 110F of the substrate 110. The front circuit structure 120 can be formed through a process such as a front end of line (FEOL) in the technical field to which embodiments of the present disclosure belong.

The front circuit structure 120 includes an individual device 121, an insulation layer 122, and a via 123.

The individual device 121 is formed on the front surface 110F of the substrate 110. The individual device 121 includes microscopic individual devices such as a transistor such as a metal-oxide-semiconductor field effect transistor (MOSFET) and/or a capacitor.

The material of the insulation layer 122 is one of silicon oxide, silicon nitride, PSG (phosphor silicate glass), or BPSG (borophospho silicate glass), but is not necessarily limited thereto.

The via 123 penetrates the insulation layer 122 and electrically connects the individual device 121 to the front wiring structure 130. The via 123 includes conductive materials, such as at least one of copper (Cu), aluminum (Al), gold (Au), silver (Ag), platinum (Pt), tin (Sn), chromium (Cr), palladium. (Pd), lead (Pb), titanium (Ti), tungsten (W) or their alloys.

The front wiring structure 130 is disposed on the front surface 110F of the substrate 110. The front wiring structure 130 is formed through a process such as a back end of line (BEOL) in the technical field to which embodiments of the present disclosure belong.

The front wiring structure 130 includes a first insulation layer 131A, a second insulation layer 131B, a wiring pad 132, a first connection pad 133, a plurality of first vias 134, one or more wiring patterns 135, one or more second vias 136, and one or more third vias 137.

The first insulation layer 131A is disposed on the front surface 110F of the substrate 110, and the second insulation layer 131B is disposed on the first insulation layer 131A.

The dielectric constant of the first insulation layer 131A is lower than the dielectric constant of the second insulation layer 131B. By forming the first insulation layer 131A with a low dielectric constant material, a fine pitch is realized and the semiconductor chip 100A can be provided with excellent PI (Power Integrity) characteristics. However, since the low dielectric constant material may have a physically weak characteristic, the physical characteristic of the first insulation layer 131A are complemented by disposing the second insulation layer 131B on the outside of the semiconductor chip 100A.

The dielectric constant of the first insulation layer 131A is less than 3.9. For example, the first insulation layer 131A includes at least one of carbon-doped silicon oxide (CDO), carbon-doped silicon nitride, organosilicate glass (OSG), silicon oxycarbide (SiOC), or porous silicon dioxide.

The dielectric constant of the second insulation layer 131B is 3.9 or more. For example, the second insulation layer 131B includes at least one of a silicon oxide or a silicon nitride, such as tetraethyl orthosilicate (TEOS).

The thickness of the first insulation layer 131A and the second insulation layer 131B is not particularly limited, and the thickness of the first insulation layer 131A may be thinner or thicker than the thickness of the second insulation layer 131B. For example, the thickness of each of the first insulation layer 131A and the second insulation layer 131B may be the same.

The wiring pad 132 electrically connects the first connection pad 133 and the through via 150. In addition, the wiring pad 132 electrically connects the wiring pattern 135 to the first connection pad 133 and the through via 150.

The wiring pad 132 is disposed at the interface of the first insulation layer 131A and the second insulation layer 131B. For example, the wiring pad 132 being disposed at the interface of the first insulation layer 131A and the second insulation layer 131B includes all cases where a side 132S3 that connects a first surface 132S1 of the wiring pad 132 to a second surface 132S2 of the wiring pad 132 opposite to the first surface 132S1 crosses the interface of the first insulation layer 131A and the second insulation layer 131B.

However, when the first surface 132S1 of the wiring pad 132 is positioned at the interface of the first insulation layer 131A and the second insulation layer 131B, due to stress applied to the first surface 132S1 of the wiring pad 132, the interface between the first insulation layer 131A and the second insulation layer 131B can separate.

In an embodiment of the present disclosure, the side surface 132S3 of the wiring pad 132 is positioned at the level where the interface of the first insulation layer 131A and the second insulation layer 131B is positioned. For example, the interface of the first insulation layer 131A and the second insulation layer 131B is positioned between the first surface 132S1 and the second surface 132S2 of the wiring pad 132. Accordingly, the side surface 132S3 adjacent to the first surface 132S1 of the wiring pad 132 is covered by the first insulation layer 131A, and the side surface 132S3 adjacent to the second surface 132S2 is covered by the second insulation layer 131B.

The first connection pad 133 electrically connects the semiconductor chip 100A with other components such as other semiconductor chips or substrates.

The first connection pad 133 is embedded in the second insulation layer 131B. One surface of the first connection pad 133 is exposed by the second insulation layer 131B, and at least part of the side surface and the other surface are covered by the second insulation layer 131B.

In an embodiment, the thickness of the first connection pad 133 is greater than the thickness of each of the wiring pad 132 and the wiring pattern 135, but embodiments are not necessarily limited thereto.

The plurality of first vias 134 are in contact with each of the wiring pad 132 and the first connection pad 133, thereby electrically connecting them.

The number of the plurality of first vias 134 may be 30 or more, 40 or more, or 50 or more. The number of the first vias 134 is greater than the number of each of the second vias 136 and the third vias 137. By placing the plurality of first vias 134 between the wiring pad 132 and the first connection pad 133, the junction force between the wiring pad 132 and the first connection pad 133 is increased.

By positioning the wiring pad 132 at the interface of the first insulation layer 131A and the second insulation layer 131B, the first via 134 is embedded in the second insulation layer 131B.

The one or more wiring patterns 135 are disposed between the substrate 110 and the wiring pad 132 and embedded in the first insulation layer 131A. In the semiconductor chip 100A, a wiring pattern is not embedded in the second insulation layer 131B, and in the BEOL process, the wiring pattern 135 is formed on a layer formed before the wiring pad 132.

The wiring patterns 135 include a plurality of wiring patterns 135 disposed in different layers. As a non-limiting example, the wiring patterns 135 include a first wiring pattern 135A, a second wiring pattern 135B, and a third wiring pattern 135C located in different layers. The first wiring pattern 135A is disposed on the substrate 110, the second wiring pattern 135B is disposed on the first wiring pattern 135A, and the third wiring pattern 135C is disposed on the second wiring pattern 135B.

Of the plurality of wiring patterns 135, the first wiring pattern 135A, which is closest to the individual device 121, is disposed on the insulation layer 122 of the front circuit structure 120 and be connected to the individual device 121 through the via 123. In addition, of the plurality of wiring patterns 135, the third wiring pattern 135C, which is closest to the wiring pad 132, is connected to the wiring pad 132 through the second via 136.

The second via 136 is in contact with each of the wiring pad 132 and the wiring pattern 135, thereby electrically connecting them. Of the plurality of wiring patterns 135, the wiring pattern 135 in contact with the second via 136 is the third wiring pattern 135C. The number of the second vias 136 that connect the wiring pad 132 and the wiring pattern 135 may be plural or single.

The one or more third vias 137 are in contact with each of the plurality of wiring patterns 135 and electrically connect them. For example, the third via 137 includes a third via 137A in contact with each of the first wiring pattern 135A and the second wiring pattern 135B and that electrically connects them, and a third via 137B in contact with each of second wiring pattern 135B and the third wiring pattern 135C and that electrically connects them.

A material of each of the wiring pad 132, the first connection pad 133, the plurality of first vias 134, the wiring pattern 135, the second via 136, and the third via 137 is conductive, such as at least one of copper(Cu), aluminum(Al), and gold. (Au), silver (Ag), platinum (Pt), tin (Sn), chromium (Cr), palladium (Pd), lead (Pb), titanium (Ti), tungsten (W) or their alloys.

The rear wiring structure 140 is disposed on the rear surface 110B of the substrate 110.

The rear wiring structure 140 includes a second connection pad 141 and a third insulation layer 142.

The second connection pad 141 electrically connects the semiconductor chip 100A to another semiconductor chip.

A conductive material is used for the second connection pad 141, such as at least one of copper(Cu), aluminum(Al), gold(Au), silver(Ag), platinum(Pt), tin(Sn), chromium (Cr), palladium (Pd), lead (Pb), titanium (Ti), tungsten (W) or their alloys.

The third insulation layer 142 is disposed at the side surface of the second connection pad 141. The third insulation layer 142 includes the same material as the second insulation layer 131B and includes at least one of, for example, silicon oxide or silicon nitride.

The through via 150 penetrates the substrate 110 and the first insulation layer 131A, and electrically connects the front wiring structure 130 and the rear wiring structure 140.

The through via 150 is in contact with the wiring pad 132 and the second connection pad 141. In addition, the through via 150 is electrically connected to the wiring pattern 135 and the first connection pad 133 by the wiring pad 132.

Conductive materials are used for the through via 150, such as at least one of tungsten (W), copper (Cu), aluminum (Al), or doped polysilicon (poly silicon), etc. In addition, the through via 150 is formed by one of a PVD process, a CVD process, or a plating process, etc.

According to an embodiment of the present disclosure, the wiring pad 132 in contact with the through via 150 is disposed at the interface of the first insulation layer 131A, which has a low dielectric constant and relatively low strength, and the second insulation layer 131B, which has a relatively high dielectric constant and relatively high strength. Stress applied to the wiring pad 132 due to temperature changes can be reduced, and the semiconductor chip 100A is provided with increased reliability. In addition, by positioning the wiring pattern 135 on the upper side of the wiring pad 132 where stress is applied, stress applied to the wiring pattern 135 due to temperature changes is also reduced. In addition, by connecting the wiring pad 132 and the first connection pad 133 through the plurality of first vias 134, the semiconductor chip 100A is provided with increased junction strength between the wiring pad 132 and the first connection pad 133.

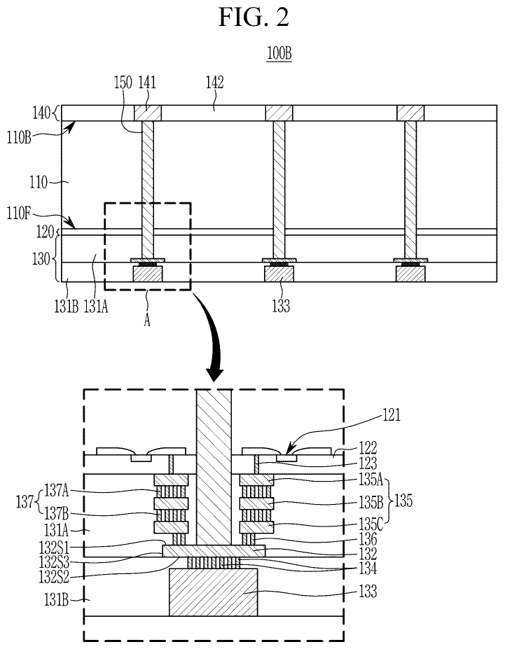

FIG. 2 is a cross-sectional view of a semiconductor chip according to an embodiment of the present disclosure.

In an embodiment of the present disclosure, the second surface 132S2 of the wiring pad 132 is positioned at the interface of the first insulation layer 131A and the second insulation layer 131B and the first surface 132S1 is covered by the first insulation layer 131A. The side surface 132S3 of the wiring pad 132 is covered by the first insulation layer 131A along with the first surface 132S1.

In an embodiment of the present disclosure, the wiring pad 132, which is connected by being in contact with the through via 150, is positioned at the interface of the first insulation layer 131A, which has a low dielectric constant and relatively low strength, and the second insulation layer 131B, which has a relatively high dielectric constant and relatively high strength. Through this, stress applied to the wiring pad 132 due to temperature changes is reduced, and thus the semiconductor chip 100B is provided with increased reliability. In addition, by positioning the wiring pattern 135 on the upper side of the wiring pad 132 where stress is applied, stress applied to the wiring pattern 135 due to temperature changes is also reduced. In addition, by connecting the wiring pad 132 and the first connection pad 133 through the plurality of first vias 134, the semiconductor chip 100B is provided with increased junction strength between the wiring pad 132 and the first connection pad 133.

Since the description of other components is the same as that described in other parts of this specification, a repeated description of these components is omitted.

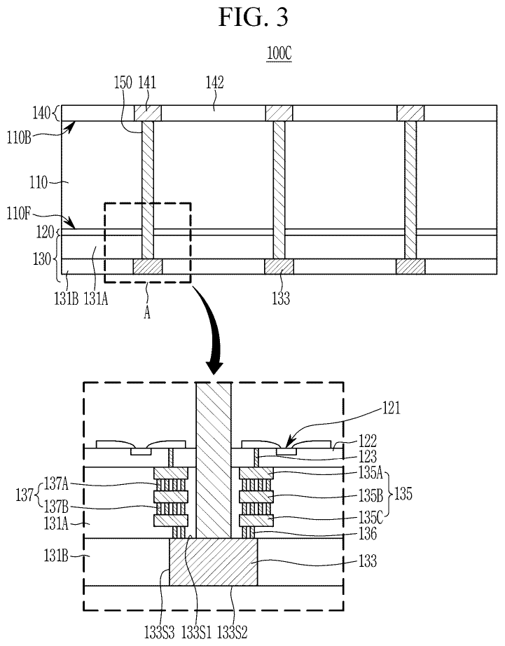

FIG. 3 is a cross-sectional view of a semiconductor chip according to an embodiment of the present disclosure.

Referring to FIG. 3, in an embodiment, the semiconductor chip 100C does not include a wiring pad that connects the through via 150 and the first connection pad 133. The through via 150 is in contact with a first surface 133S1 of the first connection pad 133 positioned at the interface of the first insulation layer 131A and the second insulation layer 131B.

The first surface 133S1 of the first connection pad 133 is covered by the first insulation layer 131A, and a second surface 133S2 is exposed by the second insulation layer 131B. In an embodiment according to FIG. 3, the first surface 133S1 of the first connection pad 133 is coplanar with a lower surface of the first insulation layer 131A. In addition, a side surface 133S3 of the first connection pad 133 is covered with the second insulation layer 131B. The thickness of the first connection pad 133 is the same as the thickness of the second insulation layer 131B.

The through via 150 is in contact with the first surface 133S1 of the first connection pad 133.

According to an embodiment of the present disclosure, instead of positioning the wiring pad at the interface of the first insulation layer 131A, which has a low dielectric constant and relatively low strength, and the second insulation layer 131B, which has a relatively high dielectric constant and relatively high strength, the first surface of the first connection pad 133 is positioned and in contact with the through via 150. Through this, the stress applied to the connection pad due to temperature changes is reduced, and thus the semiconductor chip 100C can be provided with increased reliability. In addition, by positioning the wiring pattern 135 on the upper side of the first connection pad 133 where the stress is applied, stress applied to the wiring pattern 135 due to temperature changes is also reduced.

Since the description of other components is the same as that described in other parts of this specification, a repeated description of these components is omitted.

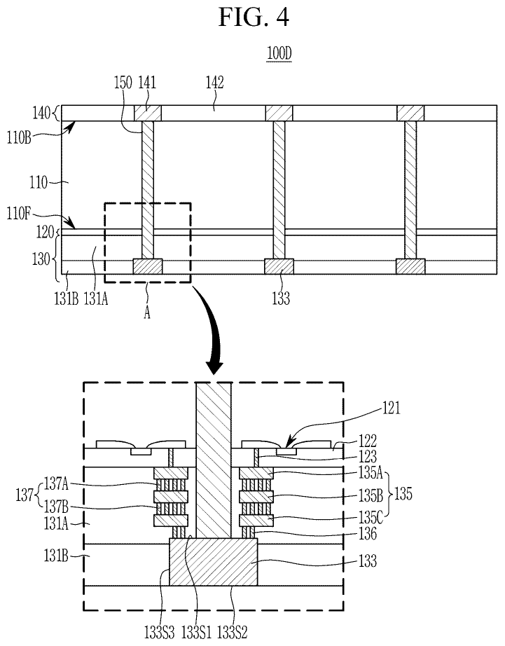

FIG. 4 is a cross-sectional view of a semiconductor chip according to an embodiment of the present disclosure.

In an embodiment according to FIG. 4, a portion of the first connection pad 133 penetrates into the first insulation layer 131A, and the first insulation layer 131A further covers the side surface 133S3 adjacent to the first surface 133S1 of the first connection pad 133. Accordingly, compared with the semiconductor chip 100C of FIG. 3, the interface between the first insulation layer 131A and the second insulation layer 131B can be prevented from peeling due to stress applied to the first surface 133S1 of the first connection pad 133.

Since the description of other components is the same as that described in other parts of this specification, a repeated description of these components is omitted.

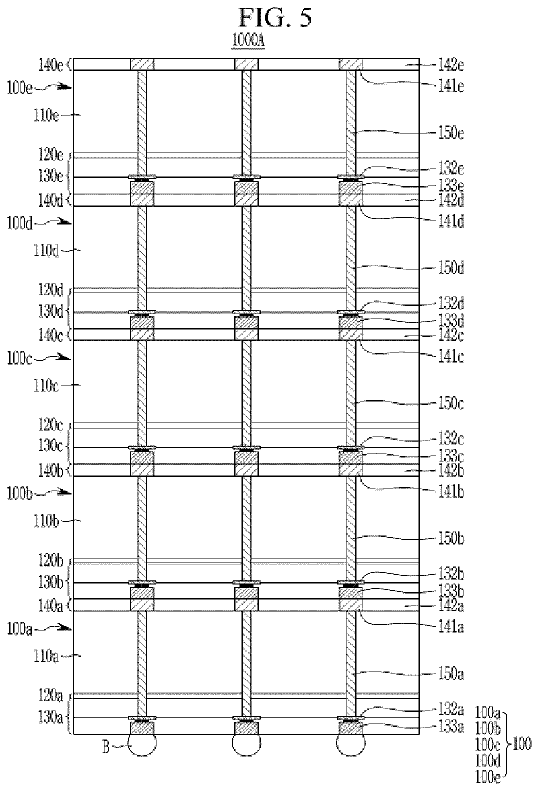

FIG. 5 is a cross-sectional view of a semiconductor package that includes a semiconductor chip according to an embodiment of the present disclosure.

Referring to FIG. 5, in an embodiment, the semiconductor package 1000A includes a plurality of semiconductor chips 100 stacked and bonded to each other. Each of the plurality of semiconductor chip 100 is one of the semiconductor chips 100A, 100B, 100C, and 100D according to embodiments of the present disclosure.

As a non-limiting example, the semiconductor package 1000A includes a first semiconductor chip 100a, a second semiconductor chip 100b, a third semiconductor chip 100c, a fourth semiconductor chip 100d, and a fifth semiconductor chip 100e bonded to each other.

The plurality of semiconductor chips 100 are hybrid bonded. Through the hybrid bonding, a fine pitch can be realized and a thinner and more reliable semiconductor package can be provided.

During the hybrid bonding, the first connection pad 133 in the front wiring structure 130 of the semiconductor chip 100 and the second connection pad 141 in the rear wiring structure 140 of the semiconductor chip 100 bonded thereto are in contact with each other and bonded. For example, the first connection pad 133b of the second semiconductor chip 100b and the second connection pad 141a of the first semiconductor chip 100a are in contact with each other and bonded.

In addition, the second insulation layer 131B in the front wiring structure 130 of the semiconductor chip 100 and the third insulation layer 142 in the rear wiring structure 140 of the semiconductor chip 100 bonded thereto are in contact with and bonded to each other. For example, the second insulation layer 131B in the front wiring structure 130b of the second semiconductor chip 100b and the third insulation layer 142a in the rear wiring structure 140a of the first semiconductor chip 100a are bonded by being in contact with each other.

In an embodiment, the plurality of semiconductor chips 100 are high bandwidth memory (HBM) chips. However, in an embodiment, the first semiconductor chip 100a, which is the lowermost of the plurality of semiconductor chips 100, is a logic chip.

On the lowermost first semiconductor chip 100a, a conductive bump B is disposed to electrically connect the semiconductor package 1000A to other components.

Since the description of other components is the same as that described in other parts of this specification, a repeated description of these components is omitted.

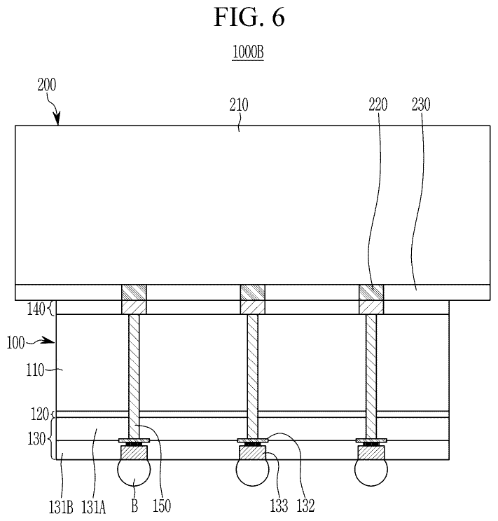

FIG. 6 is a cross-sectional view of a semiconductor package that includes a semiconductor chip according to embodiments of the present disclosure.

Referring to FIG. 6, in an embodiment, a semiconductor package 1000B includes a first semiconductor chip 100 and a second semiconductor chip 200 bonded with the first semiconductor chip 100. The second semiconductor chip 200 is bonded to the rear wiring structure 140 of the first semiconductor chip 100.

The first semiconductor chip 100 includes a substrate 110, a front circuit structure 120, a front wiring structure 130, a rear wiring structure 140, and a through via 150. In the drawing, the first semiconductor chip 100 is shown as having the structure of the semiconductor chip 100A shown in FIG. 1, but it may also have the structure of a semiconductor chip (100B, 100C or 100D) according to another embodiment.

A conductive bump B is disposed on the first connection pad 133 of the first semiconductor chip 10 and electrically connects the semiconductor package 1000B to other components.

The second semiconductor chip 200 includes a substrate 210, a connection pad 220, and an insulation layer 230. In addition, the second semiconductor chip 200 may also include other common components of a semiconductor chip, and, for example, the second semiconductor chip 200 may include a front circuit structure disposed on the substrate 210.

The substrate 210 is a semiconductor substrate that includes at least one of silicon (Si), germanium (Ge), gallium arsenide (GaAs), or silicon carbide (Sic).

The connection pad 220 electrically connects the second semiconductor chip 200 to the first semiconductor chip 100. Materials for the connection pad 220 include conductive materials such as copper (Cu), aluminum (Al), gold (Au), silver (Ag), platinum (Pt), tin (Sn), chromium (Cr), Palladium (Pd), lead (Pb), titanium (Ti), tungsten (W), or their alloys.

The insulation layer 230 is disposed on the side of the connection pad 220. The insulation layer 230 includes at least one of silicon oxide or silicon nitride.

The first semiconductor chip 100 and the second semiconductor chip 200 are hybrid bonded.

During the hybrid bonding, the second connection pad 141 in the rear wiring structure 140 of the first semiconductor chip 100 and the connection pad 220 of the second semiconductor chip 200 are in contact with each other and bonded. In addition, the third insulation layer 142 in the rear wiring structure 140 of the first semiconductor chip 100 and the insulation layer 230 of the second semiconductor chip 200 are in contact with and bond to each other.

In an embodiment, the first semiconductor chip 100 and the second semiconductor chip 200 perform different functions. For example, the first semiconductor chip 100 is a memory chip, and the second semiconductor chip 200 is a logic chip, but embodiments are not necessarily limited thereto.

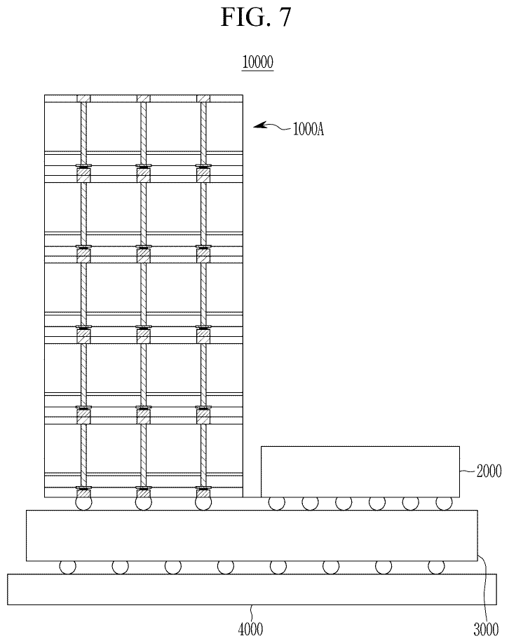

FIG. 7 is a cross-sectional view of a package that includes a semiconductor package of FIG. 5.

Referring to FIG. 7, in an embodiment, a package 10000 includes a semiconductor package 1000A, a semiconductor chip 2000, an interposer substrate 3000, and a package substrate 4000.

The semiconductor package 1000A and the semiconductor chip 2000 are disposed on the interposer substrate 3000, and the interposer substrate 3000 is disposed on the package substrate 4000.

The semiconductor chip 2000 is one of, for example, a logic chip, a central processing unit (CPU), a graphics processing unit (GPU), or a system on chip (SoC). Depending on the design, the semiconductor chip 2000 may be packaged separately and disposed on the interposer substrate 3000.

The interposer substrate 3000 electrically connects the semiconductor package 1000A, the semiconductor chip 2000, and the package substrate 4000, and corrects a line width between them.

While embodiments of this disclosure have been described in connection with the accompanying drawings, it is to be understood that embodiments of the disclosure are not limited to the disclosed embodiments. On the contrary, it is intended to cover various modifications and equivalent arrangements included within the spirit and scope of the appended claims.

What is claimed is:

1. A semiconductor chip, comprising:
a substrate;
a front wiring structure disposed on a front surface of the substrate, wherein the front wiring structure includes a first insulation layer, a second insulation layer disposed on the first insulation layer, a wiring pad, a first connection pad, and a plurality of first vias that electrically connect the wiring pad and the first connection pad;
a rear wiring structure disposed on a rear surface of the substrate and that includes a second connection pad; and
a through via that penetrates the substrate and the first insulation layer and electrically connects the front wiring structure and the rear wiring structure,
wherein a dielectric constant of the first insulation layer is lower than a dielectric constant of the second insulation layer,
the wiring pad is disposed at an interface of the first insulation layer and the second insulation layer,
the first connection pad is embedded in the second insulation layer,
the plurality of first vias is in contact with each of the wiring pad and the first connection pad, and
the through via is in contact with the wiring pad.

2. The semiconductor chip of claim 1, wherein:
the interface of the first insulation layer and the second insulation layer is located at between a first surface and a second surface of the wiring pad that is opposite to the first surface.

3. The semiconductor chip of claim 1, wherein:
a first surface of the wiring pad is located at the interface of the first insulation layer and the second insulation layer, and a second surface that is opposite to the first surface is covered by the first insulation layer.

4. The semiconductor chip of claim 1, wherein:
the front wiring structure further includes one or more wiring patterns embedded in the first insulation layer and one or more second vias in contact with each of the wiring pad and the wiring pattern and that electrically connect the wiring pad and the wiring pattern, and
a number of the first vias is greater than a number of the second vias.

5. The semiconductor chip of claim 4, wherein:
the wiring patterns include a first wiring pattern and a second wiring pattern disposed in different layers,
the front wiring structure further includes one or more third vias in contact with each of the first wiring pattern and the second wiring pattern and that electrically connect the first wiring pattern and the second wiring pattern, and
the number of the first vias is greater than a number of the third vias.

6. The semiconductor chip of claim 1, wherein:
the dielectric constant of the first insulation layer is less than 3.9.

7. The semiconductor chip of claim 1, wherein:
the first insulation layer includes at least one of carbon-doped silicon oxide (CDO), carbon-doped silicon nitride, organosilicate glass (OSG), silicon oxycarbide (SiOC), or porous silicon dioxide.

8. The semiconductor chip of claim 1, wherein:
the dielectric constant of the second insulation layer is 3.9 or higher.

9. The semiconductor chip of claim 1, wherein:
the second insulation layer includes at least one of silicon oxide or silicon nitride.

10. A semiconductor chip, comprising:
a substrate;
a front wiring structure disposed on a front surface of the substrate wherein the front wiring structure includes a first insulation layer, a second insulation layer disposed on the first insulation layer, and a first connection pad;
a rear wiring structure disposed on a rear surface of the substrate and that includes a second connection pad; and
a through via that penetrates the substrate and the first insulation layer and electrically connects the front wiring structure and the rear wiring structure,
wherein a dielectric constant of the first insulation layer is lower than a dielectric constant of the second insulation layer,
a first surface of the first connection pad is covered by the first insulation layer, and a second surface of the first connection pad opposite to the first surface is exposed by the second insulation layer, and
the through via is in contact with the first surface of the first connection pad.

11. The semiconductor chip of claim 10, wherein:
the first surface of the first connection pad is coplanar with a first surface of the first insulation layer.

12. The semiconductor chip of claim 10, wherein:
the first insulation layer further covers a side surface of the first connection pad that is adjacent to the first surface of the first connection pad.

13. The semiconductor chip of claim 10, wherein:
the front wiring structure further includes one or more wiring patterns embedded in the first insulation layer and one or more second vias in contact with each of the wiring pad and the wiring pattern and that electrically connect the wiring pad and the wiring pattern, and
a number of the first vias is greater than a number of the second vias.

14. The semiconductor chip of claim 13, wherein:
the wiring patterns include a first wiring pattern and a second wiring pattern disposed in different layers,
the front wiring structure further includes one or more third vias in contact with each of the first wiring pattern and the second wiring pattern and that electrically connect the first wiring pattern and the second wiring pattern, and
the number of the first vias is greater than a number of the third via.

15. The semiconductor chip of claim 10, wherein:
the dielectric constant of the first insulation layer is less than 3.9.

16. The semiconductor chip of claim 10, wherein:
the dielectric constant of the second insulation layer is 3.9 or higher.

17. A semiconductor package, comprising:
a first semiconductor chip; and
a second semiconductor chip bonded with the first semiconductor chip;
wherein the first semiconductor chip includes:
a first substrate;
a front wiring structure disposed on a front surface of the first substrate, wherein the front wiring structure includes a first insulation layer, a second insulation layer disposed on the first insulation layer, a wiring pad, a first connection pad, and a plurality of first vias that electrically connect the wiring pad and the first connection pad;
a rear wiring structure disposed on a rear surface of the first substrate and that includes a second connection pad; and
a through via that penetrates the first substrate and the first insulation layer and electrically connects the front wiring structure and the rear wiring structure,
wherein the second semiconductor chip includes:
a second substrate; and
a third connection pad disposed on the second substrate,
wherein a dielectric constant of the first insulation layer is lower than a dielectric constant of the second insulation layer,
the wiring pad is located at an interface of the first insulation layer and the second insulation layer,
the first connection pad is embedded in the second insulation layer,
the plurality of first vias is in contact with each of the wiring pad and the first connection pad,
the through via is in contact with the wiring pad, and
the first connection pad and the third connection pad are in contact with and bonded to each other.

18. The semiconductor package of claim 17, wherein:
the second semiconductor chip further includes a third insulation layer disposed at a side surface of the third connection pad, and
the second insulation layer and the third insulation layer are in contact with and bonded to each other.

19. The semiconductor package of claim 17, wherein:
the first semiconductor chip and the second semiconductor chip are high bandwidth memory (HBM) chips.

20. The semiconductor package of claim 17, wherein:
the first semiconductor chip and the second semiconductor chip perform different functions.
